(19) United States
(12) Patent Application Publication
(10) Pub. No.: US 2004/0104458 A1
(43) Pub. Date: Jun. 3, 2004

(54) Semiconductor deivce and method for manufacturing same

(76) Inventors: Futoshi Tsukada, Nagano (JP); Keiichi Masaki, Nagano (JP)

Correspondence Address: Staas & Halsey, Suite 500, 700 Eleventh Street NW, Washington, DC, 20001, US

(21) Appl. No.: 10/473,723

(22) PCT Filed: Feb. 6, 2003
(86) PCT No.: PCT/JP03/01265

(30) Foreign Application Priority Data
Feb. 18, 2002 (JP) 2002-040276

(51) Int. Cl. H01L 21/56

(52) U.S. Cl. 257/669; 257/787; 257/704; 257/680; 438/124; 438/127; 438/126

(57) ABSTRACT

A semiconductor element, such as a pressure sensor, having an upper surface, so that a part of the upper surface is exposed to the outside, while this element is in use. The element is sealed with a sealing resin. The sealing resin has a second, upper surface and a recess, so that said part of the first, upper surface of the semiconductor element is exposed outside at the bottom of said recess which is opened at the second, upper second surface. A releasable protective member has a shape corresponding to the recess and is placed in the recess, so that, when said protective member is in the recess, a bottom surface thereof is in contact with the part of the first, upper face of the protective member and the upper face of the resin coincides with the second surface of the sealing resin.

### TECHNICAL FIELD

The present invention relates to a semiconductor device and a manufacturing method thereof. More particularly, the present invention relates to a semiconductor device in which at least a part of a surface of a semiconductor element used for any particular functional element, such as, a pressure sensor and others, is exposed onto a bottom face of a recess portion formed on a sealing resin layer for sealing the semiconductor element. The present invention also relates to a manufacturing method of manufacturing the semiconductor device.

### BACKGROUND OF ART

Concerning a semiconductor device, there is provided a semiconductor device 30, as shown in FIG. 5, used as a pressure sensor, such as a fingerprint sensor for sensing a fingerprint of a person whose fingertip is pressed against the fingerprint sensor, as disclosed in Japanese Patent Publication No. 4-2152.

As shown in FIG. 5, in this semiconductor device 30, the surface 16a (surface of the semiconductor element 16) of the fingerprint sensing section of the semiconductor element 16, which is mounted on the die plate 14 of the lead frame 12, is exposed to a bottom face of the recess section 20 formed on the sealing resin layer 18 to seal the semiconductor element 16 and others, that is, this semiconductor device 30 is of the semiconductor element surface exposure type.

When this semiconductor device 30 of the semiconductor element surface exposure type is manufactured, first, the semiconductor element 16, which is mounted on the die plate 14 of the lead frame 12, and a forward end portion of the inner lead 24 of the lead frame 12 are subjected to wire-bonding by the wire 22 and then inserted between the upper metallic mold 100 and the lower metallic mold 102 which are open as shown in FIG. 6(a).

In this case, the lead frame 12 is inserted so that the semiconductor element 16 can be located in the cavity 104 formed by the upper metallic mold 100 and the lower metallic mold 102.

In this upper metallic mold 100, there is provided a protruding section 106 protruding into the cavity 104 so that a forward end face of the protruding portion 106 can be contacted with the surface 16a of the fingerprint sensing section of the semiconductor element 16 which has been inserted into the cavity 104 when the upper and the lower metallic mold are closed.

Next, when the upper mold 100 and the lower mold 102 are closed, as shown in FIG. 6(b), a forward end face of the protruding section 106 formed in the upper mold 100 comes into contact with the surface 16a of the fingerprint sensing section of the semiconductor element 16 which has been inserted into the cavity 104. Therefore, the surface 16a of the fingerprint sensing section of the semiconductor element 16 is covered with the forward end face of the protruding portion 106.

Under the condition that the surface 16a is covered with the forward end face of the protruding section 106, sealing resin M is injected into the cavity 104 through the resin path 108. Then, a portion in which the semiconductor element 16 exists, except for the surface 16a covered with the forward end face of the protruding section 106, the wire 22 and the inner lead 24 are sealed with sealing resin M.

After that, when the upper mold 100 and the lower mold 102 are opened from each other, it is possible to obtain a semiconductor device 30 in which the surface 16a of the fingerprint sensing section of the semiconductor element 16 is exposed onto the bottom face of the recess section 20 formed on the sealing resin layer 18 to seal the semiconductor element 16 and others with resin.

According to the manufacturing method shown in FIGS. 6(a) to 6(c), the semiconductor device 30 can be easily obtained in which the surface 16a of the fingerprint sensing section of the semiconductor element 16 is exposed onto the bottom face of the recess section 20 formed on the sealing resin layer 18.

However, according to the manufacturing method shown in FIGS. 6(a) to 6(c), the upper metallic mold 100 has a protruding section 106 which protrudes into the cavity 104 so that a forward end face of the protruding section 106 can be contacted with the surface 16a of the fingerprint sensing section of the semiconductor element 16 which has been inserted into the cavity 104 when the metallic molds are closed.

The upper mold 100 in which the protruding portion 106 is formed as described above cannot be used as a metallic mold which is commonly used for manufacturing a semiconductor device. Therefore, they have no option but to exclusively use this upper mold 100 for manufacturing the semiconductor device 30 shown in FIG. 5.

Further, the protruding section 106 protruding into the cavity 104 of the metallic mold tends to be worn out by sealing resin injected into the cavity 104, which shortens the life of the metallic mold.

Since the forward end face of the protruding section 106 protruding into the cavity 104 of the metallic mold comes into pressure contact with the surface 16a of the semiconductor element 16, resin sealing is conducted while the semiconductor element 16 is subject to stress. Therefore, cracks tend to occur in the semiconductor element 16 during the process of resin sealing, which deteriorates the yield.

Further, the surface 16a of the semiconductor element 16 of the thus obtained semiconductor device 30 is not protected at all. Accordingly, there is a possibility that the surface 16a of the semiconductor element 16 is damaged or stained while the semiconductor device 30 is being conveyed.

### DISCLOSURE OF INVENTION

It is an object of the present invention to provide a semiconductor device in which at least a part of a surface of a semiconductor element is exposed onto a bottom face of a recess portion formed on a sealing resin layer and a surface of the semiconductor element is not damaged when the semiconductor device is conveyed.

Another object of the present invention into provide a method of easily manufacturing such a semiconductor device by using a common manufacturing apparatus, such as a conventionally and commonly used molding apparatus.

In order to solve the above problems, the present inventors made repeated investigations. As a result of the investigations, the present inventors found the following. A surface portion of a semiconductor element, which is exposed onto a bottom face of a recess portion formed on a sealing resin layer, can be covered with a protective member, the profile of which follows a profile of the bottom face of the recess portion, and then resin sealing can be conducted with a metallic mold commonly used for manufacturing a semiconductor device.

Further, the present inventors found the following. In the semiconductor device in which the metallic mold is sealed with resin, a protective member, the profile of which is formed following the bottom face profile of the recess portion formed on the sealing layer, can be detachably inserted into the recess portion on the sealing resin layer. Therefore, it is possible to prevent the surface of the semiconductor element, which is exposed onto the bottom face of the recess portion on the sealing resin layer, from being damaged while the semiconductor device is being conveyed.

On the basis of the above knowledge, the present inventors further made investigation and accomplished the present invention.

According to the present invention, there is provided a semiconductor device comprising: a semiconductor element having a first surface, so that at least a part of said first surface is exposed to the outside, while this element is in a condition of use; a sealing resin for molding said semiconductor element to cover the same, said sealing resin having a second surface and a recess, so that said part of the first surface of the semiconductor element is exposed outside at the bottom of said recess which is opened at said second surface; and a releasable protective member having a shape corresponding to said recess, so that, when said protective member is placed in said recess, a bottom face of the protective member is in contact with said part of the first surface and an upper face of the protective member coincides with said second surface of the sealing resin.

According to another aspect of the present invention there is provided a method of manufacturing a semiconductor device, said method comprising the following steps of: attaching a releasable protective member to a semiconductor element having a first surface in such a manner that at least a part of said first surface is covered with said protective member; arranging a set of molds (metallic mold) to define therein a cavity in which said semiconductor element is placed and a part of said mold is in contact with said protective member at a second surface; injecting a sealing resin into said cavity to seal said semiconductor element; and removing said protective member from said first surface of the semiconductor element so that said at least a part of the first surface of the semiconductor is exposed.

According to still another aspect of the present invention there is provided a method of manufacturing a semiconductor device, said device comprising: a semiconductor element having a first surface, so that at least a part of said first surface is exposed to the outside, while this element is in a condition of use; a sealing resin for molding said semiconductor element to cover the same, said sealing resin having a second surface and a recess, so that said part of the first surface of the semiconductor element is exposed outside at the bottom of said recess which is opened at said second surface; and a releasable protective member having a shape corresponding to said recess, so that, when said protective member is placed in said recess, a bottom face of the protective member is in contact with said part of the first surface and an upper face coincides with said second surface;

said method comprising the following steps of: attaching said protective member to said semiconductor element in such a manner that at least a part of said first surface is covered with said protective member; arranging a set of molds (metallic mold) to define therein a cavity in which said semiconductor element is placed and a part of said mold is in contact with said protective member at said second surface; and injecting a sealing resin into said cavity to seal said semiconductor element.

In the present invention described above, when a protective member is used which can be easily separated or released from the sealing resin and elastically deformed and is made of heat-resistant resin which is heat-resistant with respect to a temperature of sealing resin injected into the cavity of the metallic mold, especially when a protective member is used which is made of silicone rubber or fluororesin, the protective member can be prevented from being deformed in the process of resin sealing.

According to the method of manufacturing a semiconductor device of the present invention, it is not necessary to form a protruding portion, the forward end face of which comes into contact with a predetermined face of the semiconductor element which is inserted into the cavity of the metallic mold, in the metallic mold. Therefore, it is possible to use a metallic mold commonly used for manufacturing a semiconductor device. Further, the life of the metallic mold can be extended.

According to the present invention, the exposed face of the semiconductor element is covered with a protective member and resin sealing is conducted. Therefore, compared with a case in which the forward end face of the protruding section formed in the metallic mold comes into pressure contact with a predetermined surface of the semiconductor element and resin sealing is conducted, the semiconductor element can be prevented from being given stress. Accordingly, the occurrence of cracks in the semiconductor element can be prevented in the process of resin sealing.

Further, in the thus obtained semiconductor device, a surface of the semiconductor element exposed onto the bottom face of the recess portion formed on the sealing resin layer is covered with the protective member. Therefore, it is possible to prevent the surface of the semiconductor element, which is exposed onto the bottom face of the recess portion of the sealing resin layer, from being damaged while the semiconductor device is being conveyed.

### BRIEF DESCRIPTION OF THE DRAWINGS

In the drawings:

FIGS. 1(a) and 1(b) are sectional views for explaining an example of the semiconductor device of the present invention;

FIGS. 2(a) to 2(d) are process drawings for explaining a manufacturing process of the semiconductor device shown in FIG. 1;

FIGS. 3(a) and 3(b) are sectional views for explaining another example of the semiconductor device of the present invention;

FIG. 4 is a process drawing for explaining a manufacturing process of the semiconductor device shown in FIGS. 3(a) and 3(b);

FIG. 5 is a sectional view showing a semiconductor device mounted on a mounting substrate; and

FIGS. 6(a) to 6(c) are process drawings for explaining a manufacturing process of manufacturing the semiconductor device shown in FIG. 5.

### BEST MODE FOR CARRYING OUT THE INVENTION

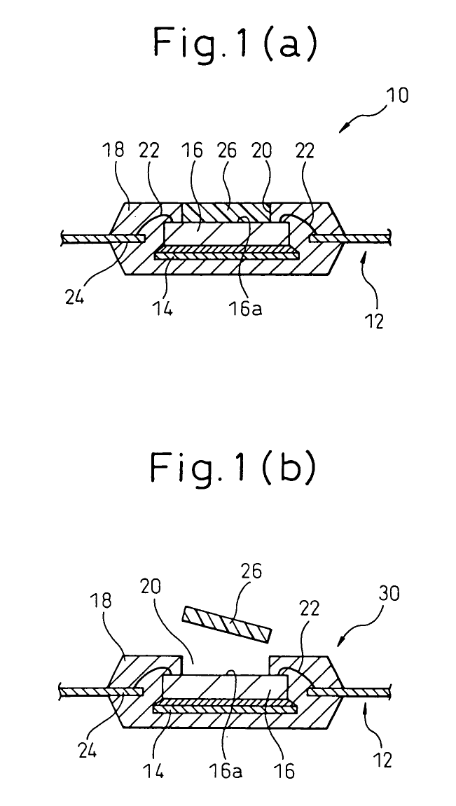

An embodiment of the semiconductor device of the present invention is shown in FIG. 1. The semiconductor device 10 shown in FIG. 1(a) is used as a fingerprint sensor. Therefore, the semiconductor device 10 includes a semiconductor element 16 provided with a fingerprint sensing section. A surface of this semiconductor element 16 may be covered with a thin protective film such as a polyimide film.

The surface 16a of the fingerprint sensing section of the semiconductor element 16, which is mounted on the die plate 14 of the lead frame 12, is exposed onto a bottom face of the recess portion 20 formed on the sealing resin layer 18 to seal the semiconductor element 16 and others. Thermosetting resin such as epoxy resin, which is commonly used, can be used as sealing resin.

The protective member 26, the profile of which is formed into the same profile as that of the surface 16a of the semiconductor element 16, is detachably inserted into this recess portion 20.

Therefore, when the protective member 26 is picked up from the recess portion 20 as shown in FIG. 1(b), the surface 16a of the fingerprint sensing section of the semiconductor element 16 can be exposed so that a human fingertip can contact the surface 16a.

When this protective member 26 is made of protective material capable of being elastically deformed and easily released from the sealing resin layer 18, the protective member 26 can be easily picked up from the recess portion 20. For the above reasons, it is preferable to use a protective member 26 made of resin capable of being easily released from the sealing resin layer 18.

However, as the protective member 26 comes into contact with sealing resin when resin sealing is conducted for sealing the semiconductor element 16 which is inserted into the cavity of the metallic mold as described later, it is preferable to use a protective member 26 made of heat-resistant resin which is heat-resistant with respect to the temperature of sealing resin injected into the cavity of the metallic mold. Especially, it is preferable to use a protective member 26 made of silicone rubber or fluororesin. From the viewpoints of enhancing the heat resistance and the separation property, the protective member made of the above materials can be most appropriately used.

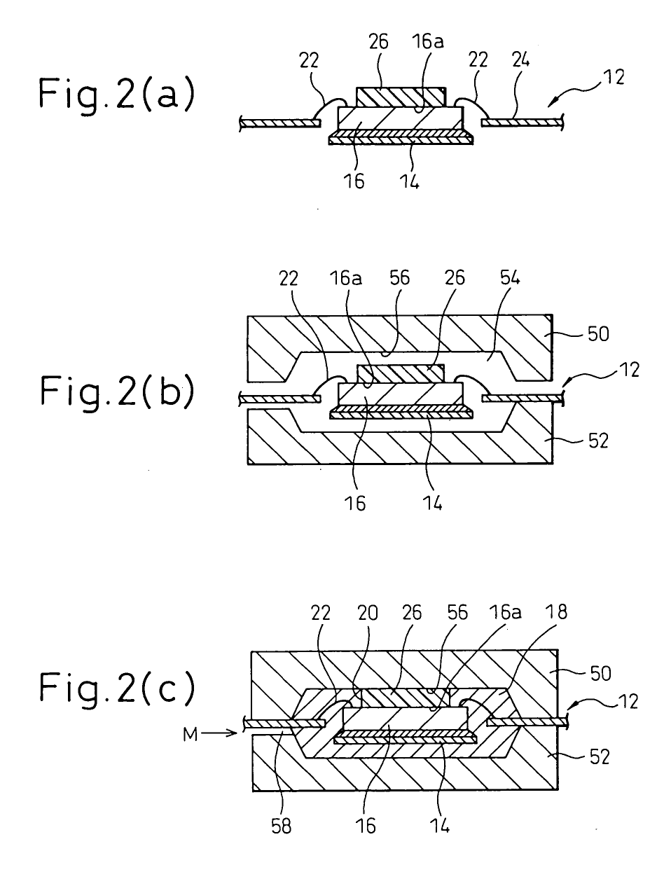

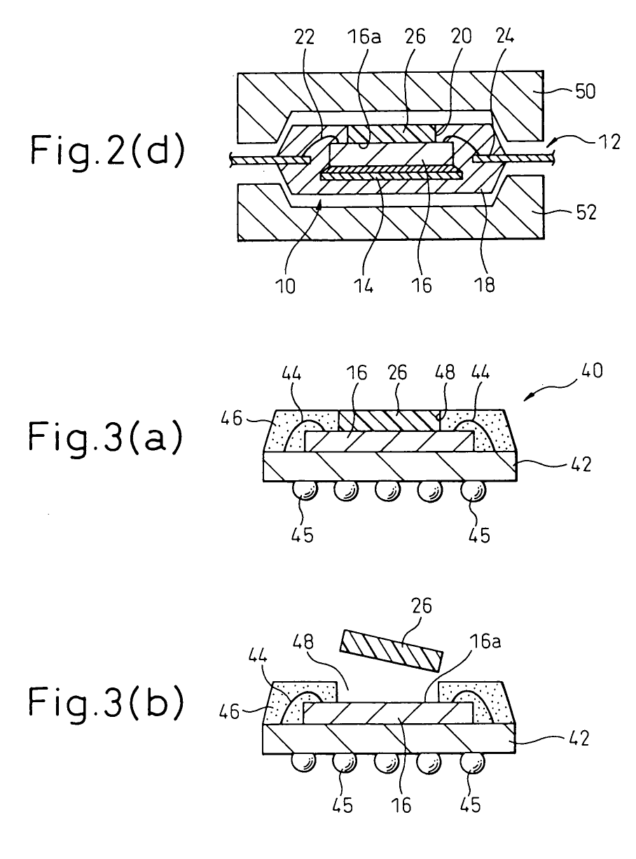

The semiconductor device 10 shown in FIG. 1(a) can be manufactured in the manufacturing process shown in FIG. 2.

First of all, the semiconductor element 16 mounted on the die plate 14 of the lead frame 12 is bonded to a forward end portion of the inner lead 24 of the lead frame 12 by the wire 22, and then the flat protective member 26 made of silicone rubber is attached onto the surface 16a, which is not sealed with sealing resin, of the fingerprint sensing section of the semiconductor element 16 as shown in FIG. 2(a). This protective member 26 can be attached onto the surface 16a without using adhesive.

It should be noted that the protective member 26 may be attached onto the surface 16a of the element 16, before the wire-bonding process of the wire 22.

Next, as shown in FIG. 2(b), the semiconductor element 16 mounted on the lead frame 12 is arranged between the upper metallic mold 50 and the lower metallic mold 52 which are open as shown in FIG. 2(b). In this case, the semiconductor element 16 is placed at a position in the cavity 54 formed by the upper metallic mold 50 and the lower metallic mold 52.

This metallic mold is composed as follows. When the semiconductor element 16 is arranged in the cavity 54, which is formed by the upper mold 50 and the low mold 52, flat inner wall faces of the cavity 54 are respectively opposed to the surface 16a, on which the fingerprint sensing section of the semiconductor element 16 is formed, and the die plate 14.

After the semiconductor element 16 mounted on the lead frame 12 has been inserted into between the upper metallic mold 50 and the lower metallic mold 52, the molds are closed. At this time, the protective member 26 attached onto the surface 16a of the fingerprint sensing section of the semiconductor element 16 comes into contact with the inner wall face of the cavity 54.

Sealing resin M is injected from the resin path 58 into the cavity 54 which is formed by closing the upper metallic mold 50 and the lower metallic mold 52. Therefore, a portion of the semiconductor element 16 except for the surface 16a covered with the protective member 26, the wire 22 and the inner lead 24 are sealed with sealing resin M as shown in FIG. 2(c). Thermosetting resin such as epoxy resin can be used as sealing resin M. When sealing resin M is injected into the cavity 54, the temperature of sealing resin M is approximately 170 to 185° C.

After sealing resin M injected into the cavity 54 has been sufficiently solidified (hardened), and when the upper mold 50 and the lower mold 52 are opened, the semiconductor device 10 can be obtained in which the surface 16a of the fingerprint sensing section of the semiconductor element 16, which is exposed onto the bottom face of the recess portion 20 formed by the resin sealing layer 18 to seal the semiconductor element 16, is covered with the protective member 26, as shown in FIG. 2(d).

Then, the protective member 26 is removed from the recess portion 20 formed on the resin sealing layer 18 of the semiconductor device 10. At this time, in the case of the semiconductor device 10 shown in FIGS. 1 and 2, the protective member 26 made of silicone rubber may be peeled off with a pair of tweezers. Alternatively, the protective member 26 can be easily detached by the electrolytic degreasing method in which electrolysis is conducted while the semiconductor device 10, dipped in an electrolytic solution, is used as a cathode or an anode.

When the above electrolytic degreasing method is adopted, in the case of conducting electrolysis while the semiconductor device 10 dipped in an electrolytic solution is being used as the cathode or anode, oxygen gas or hydrogen gas is generated by the semiconductor device 10 which is used as the cathode or anode. By the chemical action or agitating action of the thus generated gas, the protective member 26 can be easily detached.

As described above, the protective member 26 may be removed from the recess portion 20 formed on the sealing resin layer 18 of the semiconductor device 10. However, it is preferable to remove the protective member 26 from the recess portion 20 after the semiconductor device 10 has been conveyed and, especially, it is preferable to remove the protective member 26 from the recess portion 20 immediately before the semiconductor device 10 is mounted on the mounting substrate. The reason is that when the protective member 26 is picked up in this way, the surface 16a of the semiconductor element 16 exposed onto the bottom face of the recess portion 20 formed on the resin sealing layer 18 can be prevented from being damaged in the process of conveyance.

In this connection, in the case of peeling off the protective member 26 from the semiconductor device 10 with a pair of tweezers, the protective member 26 may be peeled off from the semiconductor device 10 which has already been mounted on a mounting substrate.

Explanations are made above into an example in which the present invention is applied to the semiconductor device 10 in which the semiconductor element 16 is mounted on the lead frame 12. However, it is possible to apply the present invention to the BGA (Ball Grid Array) type semiconductor device 40 as shown in FIGS. 3(a) and 3(b).

The semiconductor device 40 shown in FIG. 3(a) is a semiconductor device used as a fingerprint sensor. The semiconductor element 16 provided with a fingerprint sensing section is mounted on one side of the wiring substrate 42 and electrically connected with the wiring substrate 42 via the wires 44, 44, . . . . Onto the other side of this wiring substrate 42, the solder balls 45, 45, . . . , to be used as external connection terminals, are attached.

This semiconductor device 40 is of the one side resin sealing type in which one side of the wiring substrate 42, on which the semiconductor element 16 is mounted, is sealed with resin. The surface 16a of the fingerprint sensing section of the semiconductor element 16 is exposed onto the bottom face of the recess portion 48 on the sealing resin layer formed on the mounting face side of the semiconductor element 16 of the wiring substrate 42.

The protective member 26, the profile of which is formed into the same profile as that of the surface 16a of the semiconductor element 16, is detachably inserted into this recess portion 48. Therefore, as shown in FIG. 3(b), when the protective member 26 is detached from the recess portion 48, the surface 16a of the fingerprint sensing section of the semiconductor element 16 can be exposed so that a human fingertip can contact the surface 16a.

The semiconductor device 40 shown in FIG. 3(a) is manufactured as follows. First, the flat protective member 26 made of silicone rubber is attached onto the surface 16a, which is not sealed with sealing resin, of the fingerprint sensing section of the semiconductor element 16, which is electrically connected with the wiring substrate 42 via the wires 44, 44, . . . , mounted on one side of the wiring substrate 42.

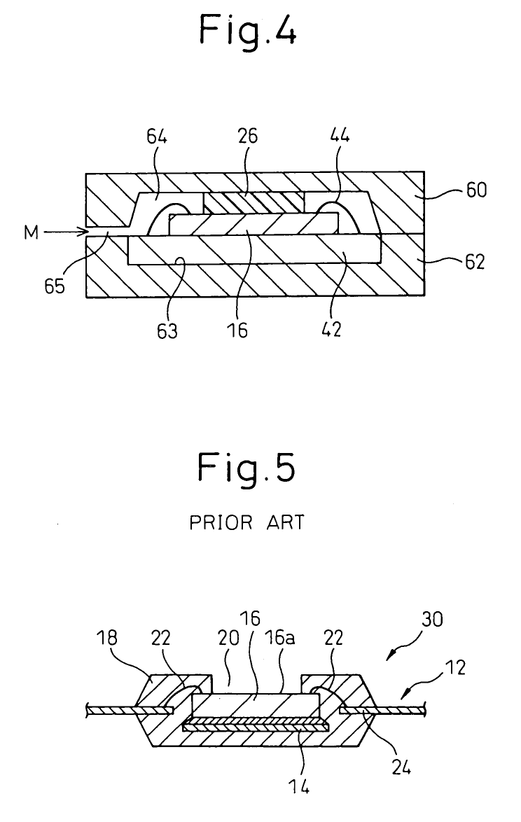

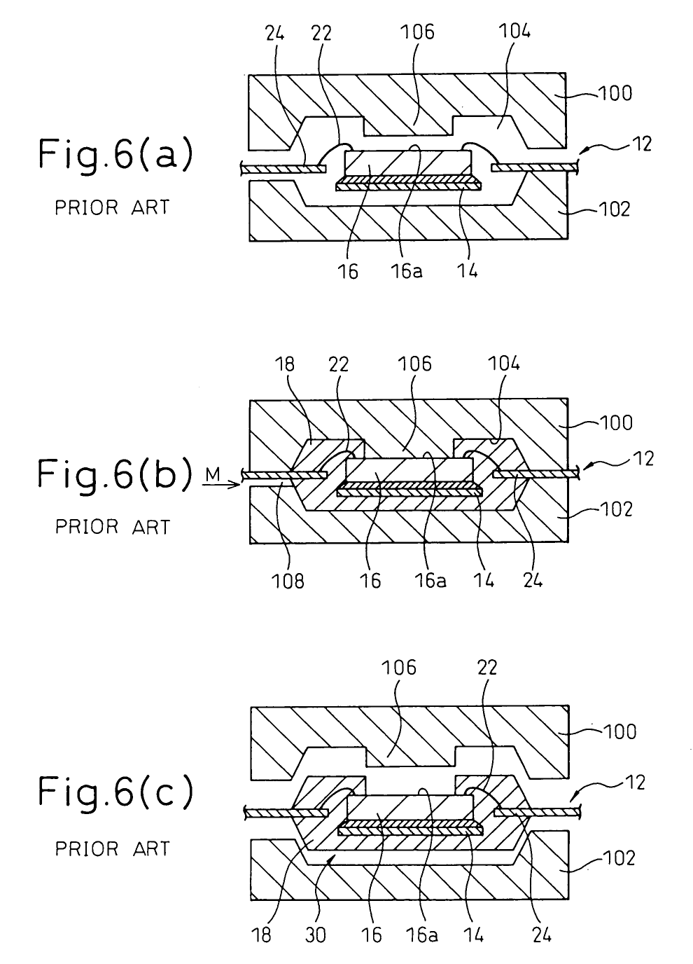

Next, as shown in FIG. 4, the wiring substrate 42 on which the semiconductor element 16 is mounted is inserted into the recess portion 63 of the lower mold 62 composing the metallic mold, and the semiconductor element 16 and the wires 44, 44, are arranged in the cavity 64 formed by the upper mold 60 and the lower mold 62. In this case, a surface of the protective member 26 attached to the semiconductor element 16 comes into contact with the inner wall face of the cavity 64.

After that, sealing resin M is injected into the cavity 64 from the resin path 65 of the metallic mold. After the sealing resin M has cooled, the metallic mold is opened, and the solder balls 45, 45, . . . are attached to predetermined positions on the wiring substrate 42 picked up from the metallic mold. In this way, the semiconductor device 40 shown in FIG. 3(a) can be obtained.

In this connection, like reference characters are used to indicate like parts of the semiconductor device and the metallic mold shown in FIGS. 1 to 4, and the detailed explanations are omitted here.

In FIGS. 1 to 4 explained above, the protective member 26 made of silicone rubber is used. However, silicone rubber exhibits a rubber-like elasticity. Therefore, when the semiconductor element 16 to which the protective member 26 made of silicone rubber is attached is arranged in the cavity 54 (64) formed by the upper mold 50 (60) and the lower mold 52 (62), the protective member 26 is contacted with and pushed by the inner wall face of the cavity 54 (64), so that the protective member 26 is easily deformed. Accordingly, a profile of the recess portion 20 formed on the sealing resin layer 18 (46) tends to fluctuate.

In order to solve the above problems, a protective member 26 made of fluororesin, which is difficult to elastically deform as compared with silicone rubber, is used. Due to the foregoing, deformation of the protective member 26, which is caused when the protective member 26 is pushed by the inner wall face of the cavity 54 (64), can be reduced as much as possible.

However, the adhesion property of the protective member 26 made of fluororesin with respect to the surface 16a of the semiconductor element 16 is lower than that of the protective member 26 made of silicone rubber. Therefore, the protective member 26 made of fluororesin may be bonded after the surface 16a has been coated with adhesive.

In this case, it is preferable that the adhesive remaining on the semiconductor element 16a is removed with solvent after the protective member 26 has been peeled off.

The semiconductor devices shown in FIGS. 1(b) and 3(b) are used as a fingerprint sensor, however, they may be used as a pressure sensor to detect pressure of the atmospheric air.

### INDUSTRIAL APPLICABILITY

According to the present invention, the protruding section, the forward end face of which comes into contact with the exposure face of the semiconductor element inserted into the cavity of the metallic mold, does not need to be formed in the metallic mold but a metallic mold commonly used for the semiconductor device can be used, and life of the metallic mold can be extended. Therefore, the manufacturing cost of the semiconductor device can be reduced.

In the case of resin sealing, resin sealing is conducted after the surface of the semiconductor element has been covered with the protective member. Therefore, stress given to the semiconductor element can be reduced. Accordingly, the occurrence of cracks caused in the semiconductor element in the process of resin sealing can be suppressed. Therefore, the yield of the thus obtained semiconductor device can be increased.

In the case of conveying the thus obtained semiconductor device, there is no possibility that the exposure face of the semiconductor element is damaged. Accordingly, the reliability of the semiconductor device can be enhanced.

It should be understood by those skilled in the art that the foregoing description relates to only a preferred embodiment of the disclosed invention, and that various changes and modifications may be made to the invention without departing the sprit and scope thereof.

1. A semiconductor device comprising:
a semiconductor element having a first surface, so that at least a part of said first surface is exposed to the outside, while the element is in use;
a sealing resin for molding said semiconductor element to cover the same, said sealing resin having a second surface and a recess, so that said part of the first surface of the semiconductor element is exposed outside at the bottom of said recess which is opened at said second surface;
a releasable protective member having a shape corresponding to said recess, so that, when said protective member is placed in said recess, a bottom face of the protective member is in contact with said part of the first surface and an upper face of the protective member coincides with said second surface of the sealing resin.

2. A semiconductor device as set forth in claim 1, wherein said semiconductor device is a pressure sensor.

3. A semiconductor device as set forth in claim 1, wherein said protective member is made of a material capable of being elastically deformed and easily released from said sealing resin, and also a heat-resistant material sufficiently endurable to a sealing temperature at a sealing process of said sealing resin.

4. A semiconductor device as set forth in claim 3, wherein said protective member is made of silicone resin or fluororesin.

5. A method of manufacturing a semiconductor device, said method comprising the following steps of:
attaching a releasable protective member to a semiconductor element having a first surface in such a manner that at least a part of said first surface is covered with said protective member;
arranging a set of molds to define therein a cavity in which said semiconductor element is placed and a part of said mold is in contact with said protective member at a second surface;
injecting a sealing resin into said cavity to seal said semiconductor element; and
removing said protective member from said first surface of the semiconductor element so that said at least a part of the first surface of the semiconductor is exposed.

6. A method as set forth in claim 5, wherein said protective member is made of a material capable of being elastically deformed and easily released from said sealing resin and from said semiconductor element, and also a heat-resistant material sufficiently endurable to a sealing temperature at a sealing process of said sealing resin.

7. A method as set forth in claim 6, wherein said protective member is made of silicone resin or fluororesin.

8. A method of manufacturing a semiconductor device, said device comprising: a semiconductor element having a first surface, so that at least a part of said first surface is exposed to the outside, while this element is in use; a sealing resin for molding said semiconductor element to cover the same, said sealing resin having a second surface and a recess, so that said part of the first surface of the semiconductor element is exposed outside at the bottom of said recess which is opened at said second surface; and a protective member having a shape corresponding to said recess, so that, when said protective member is placed in said recess, a bottom face of the protective member is in contact with said part of the first surface and an upper face of the protective member coincides with said second surface of the sealing resin;
said method comprising the following steps of:
attaching said protective member to said semiconductor element in such a manner that at least a part of said first surface is covered with said protective member;
arranging a set of molds to define therein a cavity in which said semiconductor element is placed and a part of said mold is in contact with said protective member at said second surface; and
injecting a sealing resin into said cavity to seal said semiconductor element.

9. A method as set forth in claim 8, wherein said protective member is made of a material capable of being elastically deformed and easily released from said sealing resin and from said semiconductor element, and is also a heat-resistant material capable of sufficiently withstanding a sealing temperature in a sealing process of said sealing resin.

10. A method as set forth in claim 9, wherein said protective member is made of silicone resin or fluororesin.
